(19) United States
(12) Patent Application Publication
(10) Pub. No.: US 2024/0222228 A1
(43) Pub. Date: Jul. 4, 2024

(54) DEVICES IN A SILICON CARBIDE LAYER COUPLED WITH DEVICES IN A GALLIUM NITRIDE LAYER

(71) Applicant: Intel Corporation, Santa Clara, CA (US)

(72) Inventors: Abhishek Anil SHARMA, Portland, OR (US); Han Wui THEN, Portland, OR (US); Wilfred GOMES, Portland, OR (US); Anand S. MURTHY, Portland, OR (US); Tahir GHANI, Portland, OR (US); Sagar SUTHRAM, Portland, OR (US); Pushkar RANADE, San Jose, CA (US)

(21) Appl. No.: 18/089,931

(22) Filed: Dec. 28, 2022

(51) Int. Cl. H01L 23/48; H01L 21/02; H01L 23/00; H01L 23/498; H01L 23/522; H01L 25/065; H01L 27/088

(52) U.S. Cl. CPC H01L 23/481; H01L 21/02529; H01L 21/0254; H01L 21/0262; H01L 23/49827; H01L 23/5226; H01L 24/13; H01L 25/0657; H01L 27/088; H01L 2224/13022; H01L 2224/13025; H01L 2924/05032; H01L 2924/10272; H01L 2924/1033; H01L 2924/13091; H01L 2924/1431; H01L 2924/1436

(57) ABSTRACT

Embodiments described herein may be related to apparatuses, processes, systems, and/or techniques for semiconductor packages that use devices within an SiC layer coupled with devices within a GaN layer proximate to the SiC to convert a high voltage source to the package, e.g. greater than 1 kV, to 1-1.8 V used by components within the package. The devices may be transistors. The voltage conversion will allow increased power to be supplied to the package. Other embodiments may be described and/or claimed.

### FIELD

Embodiments of the present disclosure generally relate to the field of semiconductor manufacturing, and in particular to providing high-voltages to a semiconductor during operation.

### BACKGROUND

Continued growth in virtual machines, cloud computing, and portable devices will continue to increase the demand for high density transistors within chips and packages. This is particularly true with compute dies that are interacting with large amounts of memory for high bandwidth (HBW) computing where increased amounts of power are required for operation.

### BRIEF DESCRIPTION OF THE DRAWINGS

FIGS. 1A-1B show various cross-section side views of diagrams of a semiconductor multi-layer stack that include a silicon carbide (SiC) layer next to a gallium nitride (GaN) layer to provide voltage conversion for a package, in accordance with various embodiments.

FIG. 2 shows embodiments of example structures of layers that include GaN, aluminum nitride (AlN), and/or SiC, in accordance with various embodiments.

FIG. 3A-3F illustrate cross-section side views of stages in a manufacturing process for creating 3D multi-layer stacks that include devices within a SiC layer and devices within a GaN layer that are electrically coupled with each other, in accordance with various embodiments.

FIG. 4 illustrates a side view of a diagram of a wafer scale engine (WSE) that includes Zetta memory that is powered by high voltage input that is converted using devices within a SiC layer coupled with devices within a GaN layer, in accordance with various embodiments.

FIG. 5 illustrates a method for creating a package that includes devices within a SiC layer that are electrically coupled with devices within a GaN layer on the SiC layer, in accordance with various embodiments.

FIG. 6 illustrates a computing device in accordance with one implementation of the invention.

FIG. 7 illustrates an interposer that includes one or more embodiments of the invention.

FIG. 8A illustrates a computing device in accordance with one implementation of an embodiment of the present disclosure.

FIG. 8B illustrates a processing device in accordance with one implementation of an embodiment of the present disclosure.

### DETAILED DESCRIPTION

Embodiments described herein may be related to apparatuses, processes, systems, and/or techniques for fabricating semiconductor packages that use SiC and GaN layers that are next to or proximate to each other, where devices in the SiC layer are electrically coupled with devices in the GaN layer. In particular, these devices may include transistors. These embodiments may be used to step down high-voltages, e.g. greater than 1 kV, provided to the package to 1-1.8 V for use by electrical components within the package. By providing high voltages to the package, greater electrical power is provided to operate a very large number of components, such as processor chips or memory within the package.

In embodiments, the devices in the SiC layer may be used to initially step down a higher voltage, e.g. greater than 1 kV, on one side of the SiC layer to a medium voltage, e.g. 200 V, on the other side of the SiC layer that is next to a GaN layer. Devices in the GaN layer may be used to further step down the medium voltage of 200 V to a lower voltage, for example 1-1.8 V, which may then be used by chips and other devices within the package. In embodiments, by using devices within the SiC and GaN layers to step down voltages from an initial high-voltage, a far greater amount of power may be provided to the package as opposed to legacy packages that only receive voltages between 1-1.8 V. In embodiments, a high voltage source may be provided through bumps at a side of the package.

Embodiments described herein may be used to enable Zetta scale computing. Zetta scale computing may include an extremely large number of computing devices within a package. For example, the computing devices together may provide on the order of 1021 floating-point operations per second (FLOPS). In addition, Zetta scale computing may also involve digital storage in the form of memory, for example DRAM memory, on the order of a zettabyte, or 1021 bytes within the package. The large number of computing devices and memory devices within a package may be implemented as a WSE, which may involve an entire wafer or large portions of a wafer, or multiple wafers coupled with each other, that include repeating patterns of compute circuitry on the wafers. This may be done rather than fabricating independent dies that are subsequently stitched together.

One characteristic of a WSE is that it may include components that are tens of millimeters apart. Electrically coupling such components may involve a significant IR drop. In order to mitigate this IR drop, high voltages, for example on the order of 1 kV, may be used to route power from one area of the wafer to another, which may then be converted to 1-1.8V using techniques described herein. In addition, a high-voltage supply may be used to provide significantly more power to a package. For example, a die on a wafer may consume on the order of 100 W. If there are 200 dies on a full wafer, that will requires 20 kW to power the entire wafer. And, if it is part of a WSE that may include multiple wafers bonded with each other, this power consumption will increase with each added wafer.

In legacy implementations that provide 1-1.8 V to packages, additional power may only be achieved by adding additional bumps to a side of the package to increase the number of 1-1.8 V sources to the package. However, this legacy approach may be insufficient to provide the necessary power required by Zetta computing. There is limited area on a side of the package, and increasing the number of bumps will necessarily reduce the size of each individual bump, therefore reducing the current handling ability of each bump.

In embodiments described herein, a larger amount of power may be provided to each package while not increasing the number of bumps at the side of the package. This is done by connecting the bumps to a voltage source that operates on the order of 1 kV or more. In embodiments, devices such as transistors may be implemented in a SiC layer that are coupled with the 1 kV or greater source. SiC as a semiconductor material has a higher resistivity, and as a result an SiC channel of a transistor would also be more resistive. The resistance of contacts of a transistor within an SiC layer is also high. However, these resistive characteristics are less pronounced when dealing with higher voltages, for example greater than 1 kV, within the SiC transistor. In addition, SiC is a high band gap (BG) material that handles high voltages without breaking down, and devices formed within the SiC layer may be well suited for high voltages without failing.

The GaN layer may be more suited for devices using lower voltages, for example voltages less than 1 kV. Unlike SiC, GaN supports 2D electron gas (2DEG) which provides high electron mobility (HEM) in transistor implementations. Also, GaN is far less resistive than SiC and will operate with less loss than SiC at voltages under 1 kV. In addition, at voltages in the range of 1 V to 1 kV, GaN devices will operate without failure. In embodiments, the amount of voltage used with a GaN transistor device may be based upon channel length. For example, if a GaN transistor is to handle 500V, a channel length of 1-2 microns may be used. In another example, if the GaN transistor is to handle 1 V, a 30 nm channel length may be used. In this way, SiC devices may be used to bring the incoming voltage from greater than 1 kV down to around 1 kV, and GaN devices may be use to bring the 1 kV voltage from the SiC devices down to 1-1.8 V for use by compute dies or memory dies within the package.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

In embodiments, high-Tc conductors are utilized for global routing. Implementation of embodiments described herein can include the presence of such materials in a metal layer and/or at the package level. Implementation of embodiments described herein can include the fabrication of inductors and/or through silicon vias (TSVs) with the same. Implementation of embodiments described herein can include fabrication of a separate metal stack (bonded or monolithic) for custom routing of finished product wafers. Implementation of embodiments described herein can include the introduction of high Tc superconductors (single crystal or deposited—atomic layer deposition (ALD) and/or chemical vapor deposition (CVD) may be used to reduce the IR drop across long distances including between die stitching.

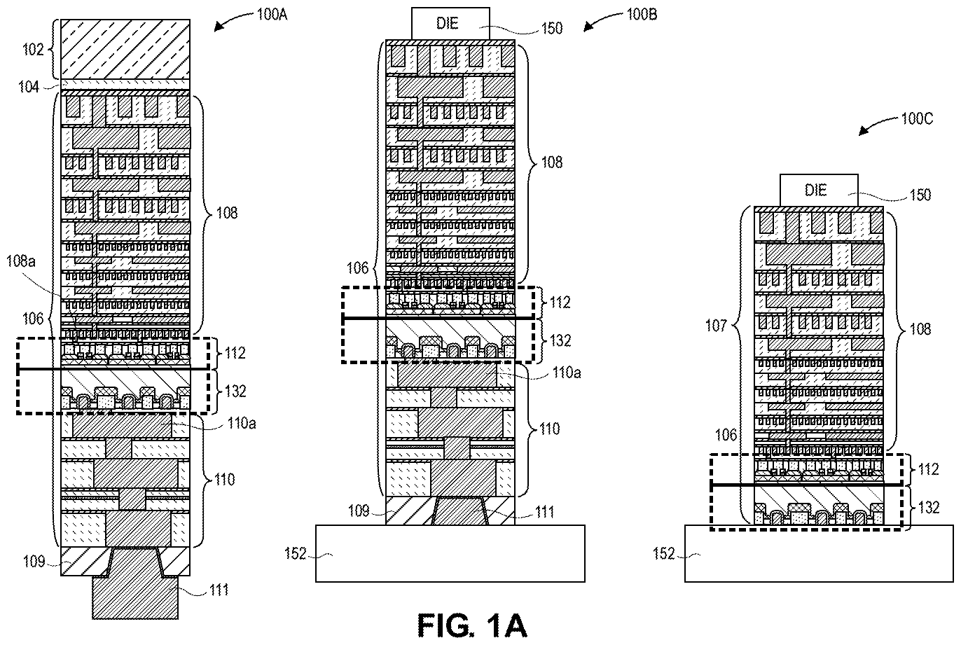

FIGS. 1A-1B show various cross-section side views of diagrams of a 3D semiconductor multi-layer stack that include a SiC layer next to a GaN layer to provide voltage conversion for a package, in accordance with various embodiments. In FIG. 1A, diagram 100A shows an embodiment that is a side view that shows a carrier wafer 102 that is bonded to a 3D multi-layer stack 106 using an adhesive 104. The 3D multi-layer stack 106 may include front side routing layers 108, which may include traces and conductive vias used to route low-voltage power and/or signals, e.g. 1-1.8 V. The 3D multi-layer stack 106 may also include back side routing layers 110, which may include power routings and conductive vias, that may route high-voltage power, e.g. handle voltage sources that are greater than 1 kV.

In embodiments, a GaN layer 112 may be below the front side routing layers 108 and various devices (described in FIG. 1B) within the GaN layer 112 may be electrically coupled with one or more of the routing elements within the front side routing layers 108, for example via 108a. A SiC layer 132 may be between the GaN layer 112 and the back side routing layers 110, and various devices (described in FIG. 1B) formed within the SiC layer 132 may be electrically coupled with one or more of the routing elements within the back side routing layers 110, for example high-voltage connector 110a. In embodiments, a bump 111, which may include a solder ball or a copper pad, may be electrically coupled with the back side routing layers 110 to provide high-voltage power from an outside source. In embodiments, the bump 111 may be surrounded by a dielectric 109.

Diagram 100B illustrates a cross-section side view that includes 3D multi-layer stack 106, with a die 150 electrically and physically coupled with a top of the front side routing layers 108. In embodiments, the die 150 may be a plurality of dies, or may be a portion of a Zetta scale plurality of compute dies or memory that is part of a WSE. The GaN layer 112 is below the front side routing layers 108, and the SiC layer 132 is below the GaN layer 112. The back side routing layers 110 are below the SiC layer 132 and above the Package 152. In embodiments, a bump 111 may electrically couple the Package 152 with the back side routing layers 110. In this embodiment, the Package 152 may provide a high-voltage source through the bump 111 to the 3D multi-layer stack 106. In embodiments, the bump 111 may be surrounded by a dielectric 109.

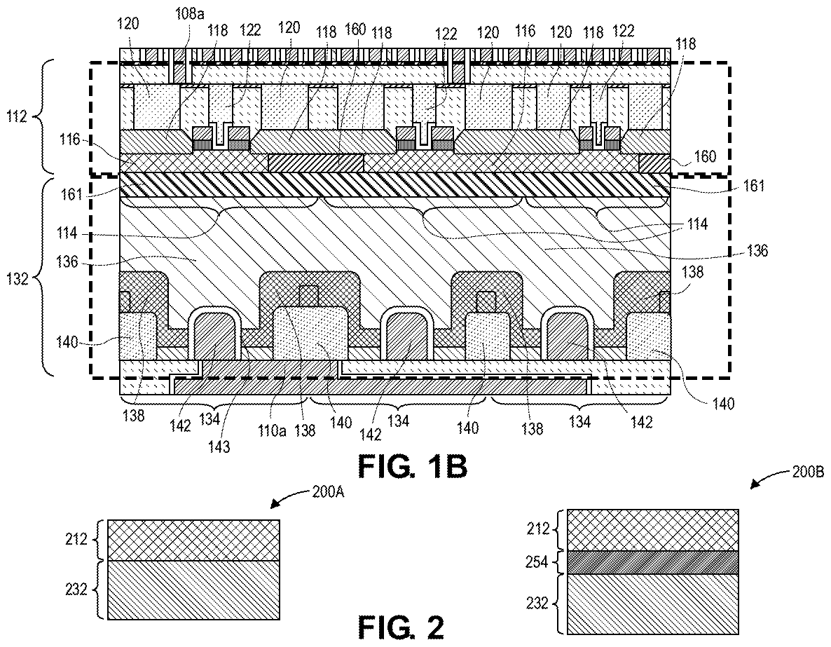

Diagram 100C illustrates a cross-section side view that includes 3D multi-layer stack 107, which may be similar to 3D multi-layer stack 106 of diagrams 100A or 100B. However, unlike the stack 106, stack 107 may include only the front side routing layers 108, the GaN layer 112 and the SiC layer 132, with a die 150 electrically and physically coupled with a top of the front side routing layers 108. In embodiments, the SiC layer 132 may be directly electrically coupled with the Package 152 that provides high-voltage, e.g. greater than 1 kV, to the SiC layer 132. Note that in other embodiments, the die 150 may be directly coupled with the GaN layer 112. In other embodiments, the GaN layer 112 may be directly coupled with the Package 152, and the SiC layer 132 may not be present. In still other embodiments, there may be an aluminum nitride (AlN) layer (not shown) that may be similar to AlN layer 254 of FIG. 2.

FIG. 1B illustrates an enlarged view of the GaN layer 112 and the SiC layer 132 of diagram 100A of FIG. 1A. In embodiments, the GaN layer 112 may include a plurality of transistors 114 that are on a GaN material 116. Each of the transistors 114 may include a doped GaN region 118 onto which contacts 120 are coupled. A gate 122 may be between the various contacts 120. In embodiments, there may be via 108a between a contact 120 and the front side routing layers 108 of FIG. 1A to provide a lower voltage, for example between 1 and 1.8 V, to the front side routing layer. Note that in this embodiment, the transistors 114 are “face up,” with the contacts 120 and the gate 122 facing toward the front side routing layers 108 of FIG. 1A. In other embodiments, the transistors 114 may be in some other configuration or some other orientation. In addition, there may be additional elements, such as interconnects, thru silicon vias and capacitors (not shown) within the GaN layer 112.

In embodiments, the SiC layer 132 may include a plurality of transistors 134 that are within a SiC material 136. The transistors 134 may include a doped region 138 onto which contacts 140 are coupled. A gate 142 may be formed between the contacts 140. In embodiments, the gate 142 may be a poly silicon gate that may be surrounded by a suitably doped semiconductor region 143. In embodiments, the gate 142 and/or the contacts 140 may be electrically coupled with the high-voltage connector 110a, that may be coupled with the back side routing layers 110 of FIG. 1A. Note that in this embodiment, the transistors 134 are “face down,” with contacts 140 and the gate 142 facing toward the back side routing layers 110 of FIG. 1A. In embodiments, this configuration may allow a more efficient, lower loss connection with the high-voltage connector 110a. In other embodiments, the transistors 134 may be in some other configuration or some other orientation. In addition, there may be additional elements, such as interconnects, thru silicon vias and capacitors (not shown) within the SiC layer 132.

In embodiments, electrical connections 160 may electrically couple the transistors 134 within the SiC layer 132 with transistors 114 within the GaN layer 112. In embodiments, the electrical connections 160 may include vias that extend at least partially through the SiC layer 132 and GaN material 116, are filled with a conductive material such as copper. In embodiments a portion 161 of the SiC material 136 may include a doping that may be an N+ doping.

FIG. 2 shows embodiments of example structures of layers that include GaN, AlN, and/or SiC, in accordance with various embodiments. Diagram 200A, which is a cross-section side view of an initial GaN layer 212, which may be similar to GaN layer 112 of FIG. 1B, and an initial SiC layer 232, which may be similar to SiC layer 132 of FIG. 1B. In embodiments, initial GaN layer 212 and initial SiC layer 232 may be fabricated prior to forming any devices, such as transistors 114 or transistors 134, within either of the initial layers. As shown in diagram 200A, the GaN layer 212 may be grown on the SiC layer 232 by epitaxial growth techniques such as metal organic chemical vapor deposition (MOCVD).

Diagram 200B is a cross-section side view of an initial GaN layer 212 on a AlN layer 254 that is on an initial SiC layer 232. In this embodiment, the AlN layer 254 may be grown on the SiC layer 232, and then subsequently the GaN layer 212 may be grown on the AlN layer 254. In embodiments, there may be an AlN layer 254 between the GaN layer 112 and the SiC layer 132 of diagrams 100A, 100B, or 100C of FIGS. 1A and 1n FIG. 1B.

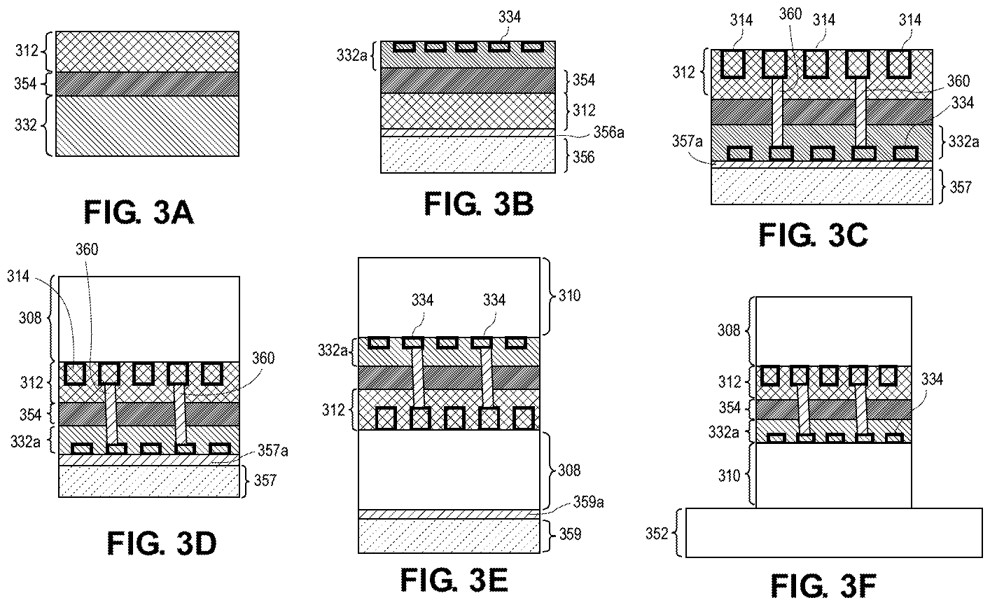

FIG. 3A-3F illustrate cross-section side views of stages in a manufacturing process for creating 3D multi-layer stacks that include devices within a SiC layer and devices within a GaN layer that are electrically coupled with each other, in accordance with various embodiments. FIG. 3A shows a cross-section side view of a stage in the manufacturing process where a SiC layer 332 is provided. In embodiments, an AlN layer 354 may be grown on top of the SiC layer 332, and a GaN layer 312 may be grown on top of the AlN layer 354. AlN layer 354, SiC layer 332, and GaN layer 312 may be similar, respectively, to AlN layer 254, SiC layer 232, and GaN layer 212 of FIG. 2. In embodiments, a thickness of the SiC layer 332 may be around 400 micrometers, a thickness of the GaN layer 312 may range from 0.5 to 10 micrometers, and a thickness of the AlN layer 354 may range from 0.05 to 0.3 micrometers. In some embodiments, the AlN layer 354 may not be included, and the GaN layer 312 may be grown directly on the SiC layer 332. FIG. 3A may be referred to as a semiconductor stack.

FIG. 3B shows a cross-section side view of a stage in the manufacturing process where the semiconductor stack in FIG. 3A, in particular the GaN layer 312, is bonded to a carrier 356 using bonding layer 356a. In embodiments, the carrier 356 may be a silicon carrier, a glass carrier, or a carrier made out of some other material. The SiC layer 332 of FIG. 3A is thinned to form SiC layer 332a, and devices 334 are formed within the thinned SiC layer 332a. For example, a thickness of the thinned SiC layer 332a may be on the order of 50 micrometers. In embodiments, the devices 334 may be similar to transistors 134 of FIG. 2.

FIG. 3C shows a cross-section side view of a stage in the manufacturing process where a new carrier 357 may be attached to the thinned SiC layer 332a, and the carrier 356 and bonding layer 356a of FIG. 3B is removed. In embodiments, the carrier 357 may be a silicon carrier, a glass carrier, or a carrier made out of some other material. Devices 314 may be formed within the GaN layer 312. In embodiments, at least some of the devices 314 may be similar to transistors 114 of FIG. 1B. In embodiments, one or more electrical connections 360, which may be similar to electrical connections 160 of FIG. 1B, may be formed between the devices 334 and the devices 314. In embodiments, the one or more electrical connections 360 may be formed by creating vias through the thinned SiC layer 332a and creating vias through the GaN layer 312. Note that thinned SiC layer 332a will reduce the distance through which the one or more electrical connections 360 will travel, thus reducing IR loss.

FIG. 3D in embodiments, front side routing layers 308, which may be similar to front side routing layers 108 of FIG. 1A, may be formed on a surface of the GaN layer 312, and may be electrically coupled with one or more of the devices 314.

FIG. 3E shows a cross-section side view of a stage in the manufacturing process where a carrier 359 is applied to the front side routing layers 308 using bonding 359a, and the carrier 357 and bonding layer 357a of FIG. 3D is removed. In embodiments, back side routing layers 310, which may be similar to back side routing layers 110 of FIG. 1A, may be formed on a surface of the SiC layer 332a and may be electrically coupled with one or more of the devices 334. As shown, high voltage, for example a voltage greater than 1 kV, enters devices 334 through the back side routing layers 310. The voltage is then converted by the devices 334 to a medium voltage, for example 200 V, and is sent to the devices 314, where the voltage is then converted to 1-1.8 V, which then enters the front side routing layers 308. In embodiments, the back side routing layers 310 may be referred to as an interconnect stack or a metal interconnect stack.

FIG. 3F shows a cross-section side view of an alternate stage in the manufacturing process where a package 352, which may be similar to package 152 of FIG. 1A, may be coupled with back side routing layers 310. In embodiments, carrier 359 and bonding 359a of FIG. 3E are removed. As a result, the package 352 may be electrically coupled with one or more of the devices 334 through the back side routing layers 310.

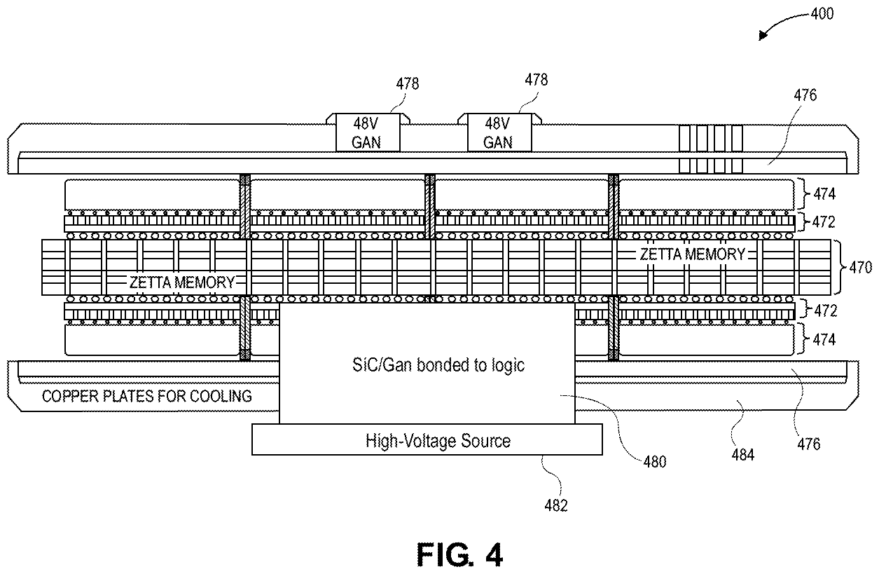

FIG. 4 illustrates a side view of a diagram of a WSE that includes logic dies and Zetta memory that is powered by high voltage input that is converted using devices within a SiC layer coupled with devices within a GaN layer, in accordance with various embodiments. WSE 400 is an embodiment that includes a plurality of layers that may include a Zetta memory 470, which may include one or more wafers that may be coupled together, where each wafer includes a plurality of memory cells.

In embodiments, interconnect layers 472 may be on the top and the bottom of the Zetta memory 470, and input/output (I/O) layers 474 may be coupled, respectively, with the interconnect layers 472. In embodiments, the I/O layers 474 may include photonics circuitry (not shown). In embodiments, a heat sink 476 may be thermally coupled with the I/O layers 474 and/or the Zetta memory 470. In embodiments, a casing 484 may at least partially surround the Zetta memory 470, the interconnect layers 472, the I/O layers 474, and/or the heat sink 476.

In embodiments, power supplies 478, which may be electrically coupled with voltage source of less than 1 kV, may include devices within a GaN layer, which may be used to step the high voltage source down to 1-1.8 V for use by the Zetta memory 470 as discussed above with respect to FIGS. 1A-1B. In embodiments, a converter 480, which may include transistors within a GaN layer and transistors within a SiC layer that are coupled with each other to step down a voltage that may be greater than 1 kV from a high voltage source 482, down to 1-1.8 V, as discussed above with respect to FIGS. 1A-1B, for use by the Zetta memory 470. In embodiments, the GaN layer may be similar to GaN layer 112 of FIGS. 1A-1B or GaN layer 212 of FIG. 2, and the SiC layer may be similar to SiC layer 132 of FIGS. 1A-1B or SiC layer 232 of FIG. 2.

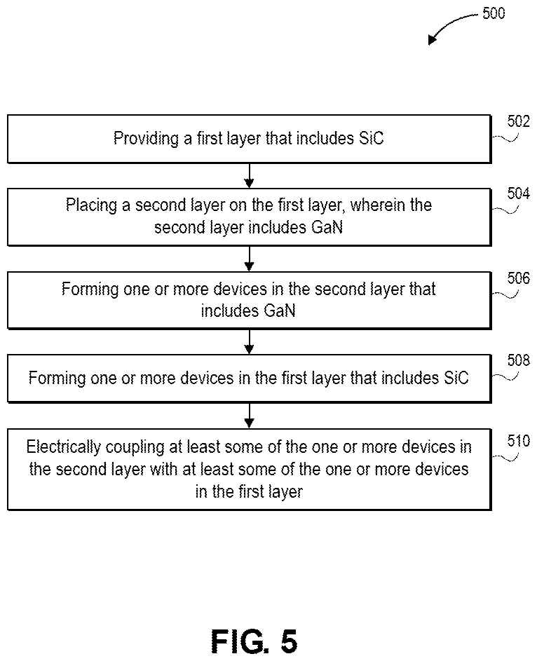

FIG. 5 illustrates an example process for creating a package that includes devices within a SiC layer that are electrically coupled with devices within a GaN layer on the SiC layer, in accordance with various embodiments. In embodiments, the process 500 may be performed using the techniques, processes, apparatus, and/or systems described herein, and in particular with respect to FIGS. 1A-4.

At block 502, the process may include providing a first layer that includes SiC. In embodiments, the first layer may be similar to SiC layer 132 of FIGS. 1A-1B or SiC layer 332, 332a of FIGS. 3A-3F.

At block 504, the process may further include placing a second layer on the first layer, wherein the second layer includes GaN. In embodiments, the second layer may be similar to GaN layer 112 of FIGS. 1A-1B or GaN layer 312 of FIGS. 3A-3F.

At block 506, the process may further include forming one or more devices in the second layer that includes GaN. In embodiments, the one or more devices in the second layer may be similar to devices 314 of FIG. 3B.

At block 508, the process may further include forming one or more devices in the first layer that includes SiC. In embodiments, the one or more devices in the first layer may be similar to devices 334 of FIG. 3D.

At block 510, the process may further include electrically coupling at least some of the one or more devices in the second layer with at least some of the one or more devices in the first layer. In embodiments, the electrical coupling may be similar to electrical connections 160 of FIG. 1B or electrical connections 360 of FIG. 3D.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

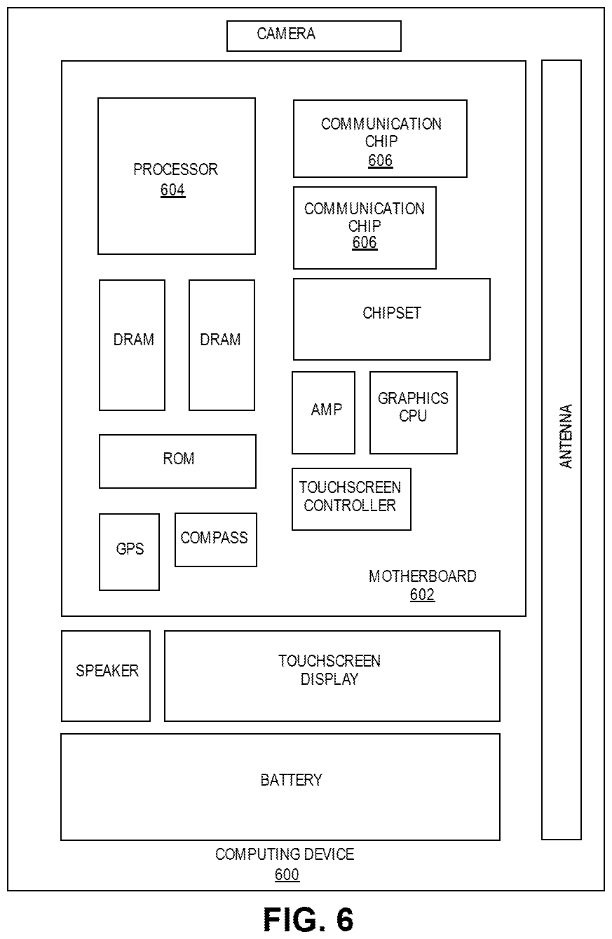

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as MOS-FET transistors built in accordance with implementations of the invention.

In further implementations, another component housed within the computing device 600 may contain an integrated circuit die that includes one or more devices, such as MOS-FET transistors built in accordance with implementations of the invention.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

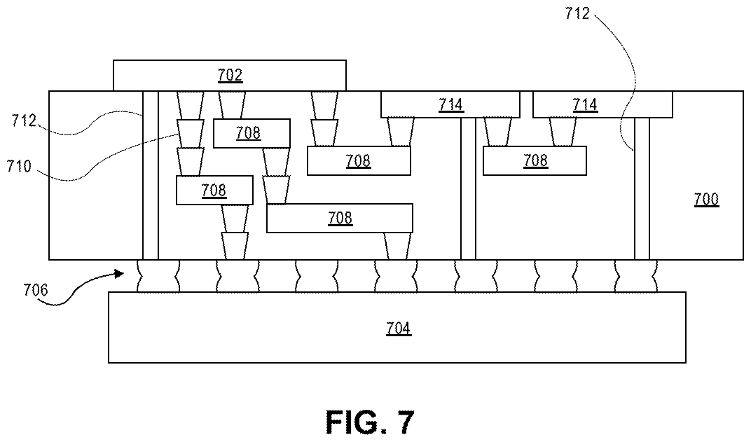

FIG. 7 illustrates an interposer 700 that includes one or more embodiments of the invention. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the invention, apparatuses or processes disclosed herein may be used in the fabrication of interposer 700.

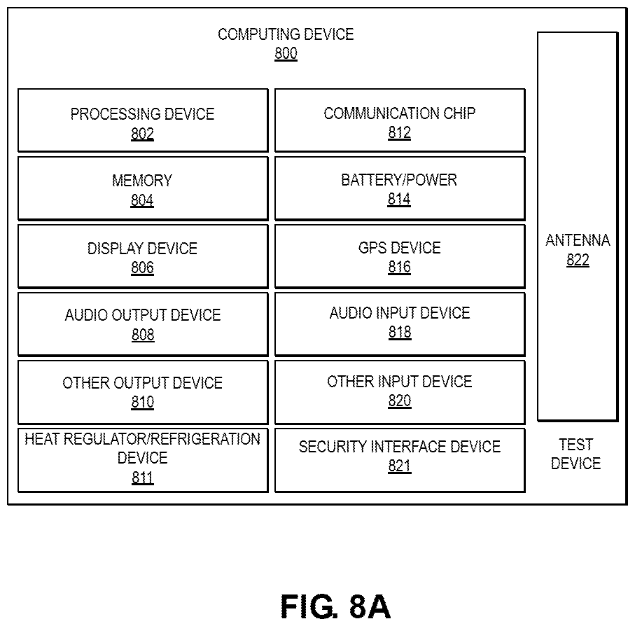

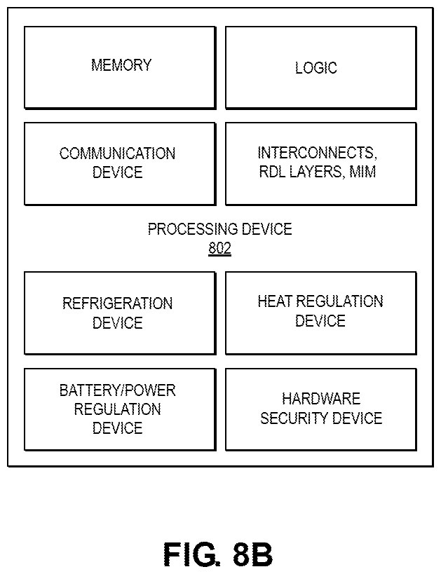

It is to be appreciated that structures described herein may be operated at a low temperature, e.g., in a range of −77 degrees Celsius to 0 degrees Celsius. In one embodiment, a heat regulator/refrigeration device is coupled to a common board having a device with structures such as those described herein coupled thereto, such as described below in association with FIG. 8A. In one embodiment, a heat regulator device and/or refrigeration device is included on a processing device having structures such as those described herein, such as described below in association with FIG. 8B.

FIG. 8A illustrates a computing device 800 in accordance with one implementation of an embodiment of the present disclosure. The computing device 800 houses a board. The board may include a number of components, including but not limited to a processing device 802. The computing device 800 can also include communication chip 812. In one embodiment, the processing device 802 is physically and electrically coupled to the board. In some implementations the communication chip 812 is also physically and electrically coupled to the board. In further implementations, the communication chip 812 is part of the processing device 802.

Depending on its applications, computing device 800 may include other components that may or may not be physically and electrically coupled to the board. These other components can include, but are not limited to, memory 804, such as volatile memory (e.g., DRAM), non-volatile memory (e.g., ROM), or flash memory, an antenna 822, a display device 806, a battery/power 814, an audio output device 808, an audio input device 818, a global positioning system (GPS) device 816, an other output device 810 (such as video output), and other input device 820 (such as video input), a security interface device 821, and/or a test device. In one embodiment, a heat regulation/refrigeration device 811 is included and is coupled to the board, e.g., a device including actively cooled copper channels.

The communication chip 812 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 812 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 812. For instance, a first communication chip 812 may be dedicated to shorter range wireless communications such as Wi-Fi and Bluetooth and a second communication chip 812 may be dedicated to longer range wireless communications such as GPS, EDGE, GPRS, CDMA, WiMAX, LTE, Ev-DO, and others.

The processing device 802 of the computing device 800 can include an integrated circuit die in a package. The processing device 802 may include one or more structures, such as gate-all-around integrated circuit structures having ultra-high conductivity global routing, built in accordance with implementations of embodiments of the present disclosure. The term “processing device” may refer to any device or portion of a device that processes electronic data from registers and/or memory to transform that electronic data into other electronic data that may be stored in registers and/or memory.

FIG. 8B illustrates a processing device in accordance with one implementation of an embodiment of the present disclosure. Referring to FIG. 8B, an exemplary processing device 802 includes a memory region, a logic region, a communication device region, an interconnects and redistribution layer (RDL) and metal-insulator-metal (MIM) region, a refrigeration device region, a heat regulation device region, a batter/power regulation device region and a hardware security device region. In one embodiment, the refrigeration device region and/or the heat regulation device region is a region including actively cooled copper channels.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs describe examples of various embodiments.

### EXAMPLES

Example 1 is an apparatus comprising: a first layer that includes silicon (Si) and carbon (C); a second layer that includes gallium (Ga) and nitrogen (N), wherein a side of the first layer and a side of the second layer are physically coupled with each other; a first device within the first layer; and a second device within the second layer, wherein the first device and the second device are electrically coupled with each other.

Example 2 includes the apparatus of example 1, wherein the first device includes a first transistor and wherein the second device includes a second transistor.

Example 3 includes the apparatus of example 2, wherein the first transistor includes a channel that includes Si and C and wherein the second transistor includes a channel that includes Ga and N.

Example 4 includes the apparatus of examples 1, 2, or 3, wherein the first device and the second device are electrically coupled with each other at least partially by a via that includes electrically conductive material, and wherein the via is electrically coupled with the first device and extends through at least a portion of the first layer.

Example 5 includes the apparatus of examples 1, 2, 3, or 4, wherein the side of the first layer is a first side of the first layer, and wherein the first device is at the first side of the first layer or at a second side of the first layer opposite the first side of the first layer.

Example 6 includes the apparatus of examples 1, 2, 3, 4, or 5, wherein the side of the second layer is a first side of the second layer, and wherein the second device is at the first side of the second layer or at a second side of the second layer opposite the first side of the second layer.

Example 7 includes the apparatus of examples 1, 2, 3, 4, 5, or 6, wherein the first layer that includes Si and C is grown on the second layer that includes Ga and N, or wherein the second layer that includes Ga and N is grown on the first layer that includes Si and C.

Example 8 includes the apparatus of examples 1, 2, 3, 4, 5, 6, or 7, further comprising: a third layer that includes aluminum (Al) and nitrogen (N); and wherein the third layer is between the side of first layer and the side of second layer.

Example 9 includes the apparatus of example 8, wherein the second layer that includes Ga and N is grown on the third layer that includes Al and N.

Example 10 includes the apparatus of examples 1, 2, 3, 4, 5, 6, 7, 8, or 9, wherein the side of the first layer is a first side, and further comprising a second side of the first layer opposite the first side of the first layer, wherein the second side of the first layer includes one or more electrical contacts that are electrically coupled with the first device.

Example 11 includes the apparatus of examples 1, 2, 3, 4, 5, 6, 7, 8, 9, or 10, wherein the side of the second layer is a first side, and further comprising a second side of the second layer opposite the first side of the second layer, wherein the second side of the second layer includes one or more electrical contacts that are electrically coupled with the second device.

Example 12 includes the apparatus of examples 1, 2, 3, 4, 5, 6, 7, 8, 9, 10, or 11, wherein a thickness of the first layer that includes Si and C is 50 microns or less.

Example 13 includes the apparatus of examples 1, 2, 3, 4, 5, 6, 7, 8, 9, 10, 11, or 12, wherein the second device is coupled with a die.

Example 14 includes the apparatus of examples 1, 2, 3, 4, 5, 6, 7, 8, 9, 10, 11, 12, or 13, wherein the first layer is part of a first wafer and the second layer is part of a second wafer.

Example 15 is a system comprising: a 3D semiconductor multi-layer stack that includes: a first layer that includes silicon (Si) and carbon (C), wherein the first layer includes a first transistor; a second layer on the first layer, wherein the second layer includes gallium (Ga) and nitrogen (N) wherein the second layer includes a second transistor; and an electrical routing that electrically couples the first transistor with the second transistor; and a package electrically coupled with the 3D semiconductor multi-layer stack.

Example 16 includes the system of example 15, wherein the first layer that includes Si and C is directly electrically coupled with the package through a metal interconnect stack.

Example 17 includes the system of examples 15 or 16, wherein the package is electrically coupled with the first transistor through the metal interconnect stack.

Example 18 includes the system of examples 15, 16, or 17, wherein the electrical routing includes a via that extends through at least a portion of the first layer that includes Si and C, and wherein the via includes a material that is electrically conductive.

Example 19 includes the system of examples 15, 16, 17, or 18, wherein the first transistor includes a channel that includes SiC and wherein the second transistor includes a channel that includes Ga and N.

Example 20 includes the system of examples 15, 16, 17, 18, or 19, wherein the second transistor includes a plurality of second transistors.

Example 21 includes the system of examples 15, 16, 17, 18, 19, or 20, further comprising a third layer that includes aluminum (Al) and nitrogen (N) between the first layer and the second layer.

Example 22 is a method comprising: providing a first layer that includes silicon (Si) and carbon (C); placing a second layer on the first layer, wherein the second layer includes gallium (Ga) and nitrogen (N); forming one or more devices in the second layer that includes Ga and N; forming one or more devices in the first layer that includes Si and C; and electrically coupling at least some of the one or more devices in the second layer with at least some of the one or more devices in the first layer.

Example 23 includes the method of example 22, wherein after the step of providing the first layer that includes SiC, further comprising providing a third layer that includes aluminum (Al) and nitrogen (N) on the first layer that includes Si and C, wherein the second layer is on the third layer.

Example 24 includes the method of examples 22 or 23, wherein providing the second layer further includes growing the second layer on the first layer.

Example 25 includes the method of examples 22, 23, or 24, wherein at least some of the one or more devices in the first layer and at least some of the one or more devices in the second layer include a transistor.

What is claimed is:

1. An apparatus comprising:
a first layer that includes silicon (Si) and carbon (C);
a second layer that includes gallium (Ga) and nitrogen (N), wherein a side of the first layer and a side of the second layer are physically coupled with each other;
a first device within the first layer; and
a second device within the second layer, wherein the first device and the second device are electrically coupled with each other.

2. The apparatus of claim 1, wherein the first device includes a first transistor and wherein the second device includes a second transistor.

3. The apparatus of claim 2, wherein the first transistor includes a channel that includes Si and C and wherein the second transistor includes a channel that includes Ga and N.

4. The apparatus of claim 1, wherein the first device and the second device are electrically coupled with each other at least partially by a via that includes electrically conductive material, and wherein the via is electrically coupled with the first device and extends through at least a portion of the first layer.

5. The apparatus of claim 1, wherein the side of the first layer is a first side of the first layer, and wherein the first device is at the first side of the first layer or at a second side of the first layer opposite the first side of the first layer.

6. The apparatus of claim 1, wherein the side of the second layer is a first side of the second layer, and wherein the second device is at the first side of the second layer or at a second side of the second layer opposite the first side of the second layer.

7. The apparatus of claim 1, wherein the first layer that includes Si and C is grown on the second layer that includes Ga and N, or wherein the second layer that includes Ga and Nis grown on the first layer that includes Si and C.

8. The apparatus of claim 1, further comprising:
a third layer that includes aluminum (Al) and nitrogen (N); and
wherein the third layer is between the side of first layer and the side of second layer.

9. The apparatus of claim 8, wherein the second layer that includes Ga and N is grown on the third layer that includes Al and N.

10. The apparatus of claim 1, wherein the side of the first layer is a first side, and further comprising a second side of the first layer opposite the first side of the first layer, wherein the second side of the first layer includes one or more electrical contacts that are electrically coupled with the first device.

11. The apparatus of claim 1, wherein the side of the second layer is a first side, and further comprising a second side of the second layer opposite the first side of the second layer, wherein the second side of the second layer includes one or more electrical contacts that are electrically coupled with the second device.

12. The apparatus of claim 1, wherein a thickness of the first layer that includes Si and C is 50 microns or less.

13. The apparatus of claim 1, wherein the second device is coupled with a die.

14. The apparatus of claim 1, wherein the first layer is part of a first wafer and the second layer is part of a second wafer.

15. A system comprising:
a 3D semiconductor multi-layer stack that includes:
a first layer that includes silicon (Si) and carbon (C), wherein the first layer includes a first transistor;
a second layer on the first layer, wherein the second layer includes gallium (Ga) and nitrogen (N), and wherein the second layer includes a second transistor; and
an electrical routing that electrically couples the first transistor with the second transistor; and
a package electrically coupled with the 3D semiconductor multi-layer stack.

16. The system of claim 15, wherein the first layer that includes Si and C is directly electrically coupled with the package through a metal interconnect stack.

17. The system of claim 15, wherein the package is electrically coupled with the first transistor through the metal interconnect stack.

18. The system of claim 15, wherein the electrical routing includes a via that extends through at least a portion of the first layer that includes Si and C, and wherein the via includes a material that is electrically conductive.

19. The system of claim 15, wherein the first transistor includes a channel that includes Si and C and wherein the second transistor includes a channel that includes Ga and N.

20. The system of claim 15, wherein the second transistor includes a plurality of second transistors.

21. The system of claim 15, further comprising a third layer that includes aluminum (Al) and nitrogen (N) between the first layer and the second layer.

22. A method comprising:
providing a first layer that includes silicon (Si) and carbon (C);
placing a second layer on the first layer, wherein the second layer includes gallium (Ga) and nitrogen (N);
forming one or more devices in the second layer that includes Ga and N;
forming one or more devices in the first layer that includes Si and C; and
electrically coupling at least some of the one or more devices in the second layer with at least some of the one or more devices in the first layer.

23. The method of claim 22, wherein after the step of providing the first layer that includes SiC, further comprising providing a third layer that includes aluminum (Al) and nitrogen (N) on the first layer that includes Si and C, wherein the second layer is on the third layer.

24. The method of claim 22, wherein providing the second layer further includes growing the second layer on the first layer.

25. The method of claim 22, wherein at least some of the one or more devices in the first layer and at least some of the one or more devices in the second layer include a transistor.
